(19) United States
(12) Patent Application Publication
(10) Pub. No.: US 2011/0235296 A1
(43) Pub. Date: Sep. 29, 2011

(54) Integrated circuit package component with ball conducting joints

(75) Inventors: Hong-Bin Shi, Shanghai (CN); Jin-Chang Wu, Taipei County (TW)

(73) Assignees: Quanta Computer Inc., Tao Yuan Shien (TW); Tech-Front (shanghai) Computer Co. Ltd., Shanghai (CN)

(21) Appl. No.: 12/805,326

(22) Filed: Jul. 26, 2010

(30) Foreign Application Priority Data
Mar. 29, 2010 (CN) 201010133899.6

(51) Int. Cl. H05K 7/00

(52) U.S. Cl. 361/783

(57) ABSTRACT

The present invention relates to an integrated circuit package component with ball conducting joints, includes a substrate and a plurality of solder joints. The solder joints are installed on one surface of the substrate. The solder joints are arranged to form a concentric array having a first zone and a second zone, the second zone encircles the first zone. The soldering area of any solder joint in the first zone of the concentric array is smaller than that of any solder joint in the second zone of the concentric array.

### RELATED APPLICATIONS

This application claims priority to Chinese Application Serial Number 201010133899.6, filed Mar. 29, 2010, which is herein incorporated by reference.

### BACKGROUND

1. Technical Field

The present invention relates to an integrated circuit package component, more particularly to a solder joint arrangement of an integrated circuit package component.

2. Description of Related Art

Generally, an integrated circuit package component is soldered on a printed circuit board through a plurality of small solder joints, so as to achieve electrical and mechanical connections between the integrated circuit package component and the printed circuit board. Due to different elasticity and coefficient of thermal expansion of the integrated circuit package component and the printed circuit board, when subject to mechanical or thermal stress, the warping levels of the integrated circuit package component and the printed circuit board are different, such conditions may result in solder joints between the integrated circuit package component and the printed circuit board being broken or damaged.

For example, sizes of solder joints of a conventional ball grid array (BGA) for an integrated circuit package component are substantially the same, and the solder joints are provided on an installation surface of the integrated circuit package component with a square rectangular array arrangement means. When the ball grid array of integrated circuit package component is subject to mechanical stress (e.g. during installation or transportation) or thermal stress (e.g. high temperature during soldering), a certain level of warping is generated and breaks would be generated once the generated warping execeeds the endurance of the solder joints, and the electrical and mechanical (physical) connections provided by the solder joints are no longer served. As such, signals are not able to be transmitted between the integrated circuit package component and the printed circuit board.

So how to develop an integrated circuit package component capable of improving the described disadvantages and inconveniences shall be concerned.

### SUMMARY

One object of the present invention is to provide an integrated circuit package component with ball conducting joints, for increasing the tensile strength of solder joints of integrated circuit package component so as to lower the possibility of breaking due to warping generated when subject to a stress.

Another object of the present invention is to provide an integrated circuit package component with ball conducting joints, for packaging larger-sized integrated circuit package components.

The integrated circuit package component with ball conducting joints comprises a substrate and a plurality of solder joints. The substrate is formed with a first surface and an opposite second surface. The solder, joints are arranged on the second surface to form a concentric array, for being soldered on a printed circuit board. The concentric array includes a first zone and a second zone, the second zone encircles the first zone. The soldering area of any solder joint in the first zone is smaller than that of any solder joint in the second zone.

Another solution provided by the present invention is to provide an integrated circuit package component with ball conducting joints, includes a substrate, a plurality of first solder joints and a plurality of second solder joints. The substrate is formed with a first surface and an opposite second surface. The first solder joints are arranged on the second surface so as to form a first zone. The second solder joints are arranged on the second surface so as to form a second zone, the second zone encircles the first zone; wherein soldering areas of the solder joints in the first zone are smaller than that of the solder joints in the second zone. One another solution provided by the present invention is to provide an integrated circuit package component with ball conducting joints, comprises a substrate and a plurality of solder joints. The substrate is formed with a first surface and an opposite second surface. The solder joints are arranged on the second surface to form a concentric circle array, the concentric circle array includes a plurality of gradually-enlarged circles arranged in sequence, soldering areas of the solder joints of the circles are the same.

Compared to conventional square rectangular array arrangement means for solder joints, the present invention effectively increase the structural strength of integrated circuit package component on a printed circuit board, so as to increase the anti-fatigue capability and reliability of the integrated circuit package component, and the size of integrated circuit package component is also appropriately reduced.

### BRIEF DESCRIPTION OF THE DRAWINGS

FIG. 1 is a distribution diagram of equal stress lines of an integrated circuit package component when being stressed.

FIG. 2 is a cross sectional view of the integrated circuit package component of one embodiment of the present invention being soldered on a circuit board.

FIG. 3A is a schematic view illustrating an arrangement means of solder joints of the integrated circuit package component of one embodiment of the present invention.

FIG. 3B is a schematic view illustrating another arrangement means of solder joints of one embodiment of the present invention.

FIG. 3C is a schematic view illustrating another method of arranging solder joints of one embodiment of the present invention.

FIG. 3D is a schematic view illustrating still another method of arranging solder joints of one embodiment of the present invention.

FIG. 4A is a schematic view illustrating an arrangement means of solder joints of the integrated circuit package component of another embodiment of the present invention.

FIG. 4B is a schematic view illustrating another arrangement means of solder joints of the integrated circuit package component of another embodiment of the present invention.

FIG. 4C is a schematic view illustrating another method of arranging solder joints of the integrated circuit package component of another embodiment of the present invention.

FIG. 4D is a schematic view illustrating still another method of arranging solder joints of the integrated circuit package component of another embodiment of the present invention.

FIG. 5A is a schematic view illustrating an arrangement means of solder joints of the integrated circuit package component of one another embodiment of the present invention.

FIG. 5B is a schematic view illustrating another arrangement means of solder joints of the integrated circuit package component of one another embodiment of the present invention.

FIG. 5C is a schematic view illustrating another method of arranging solder joints of the integrated circuit package component of one another embodiment of the present invention.

FIG. 6A is a schematic view illustrating an arrangement means of solder joints of the integrated circuit package component of still one another embodiment of the present invention.

FIG. 6B is a schematic view illustrating another arrangement means of solder joints of the integrated circuit package component of still one another embodiment of the present invention.

FIG. 6C is a schematic view illustrating another method of arranging solder joints of the integrated circuit package component of still one another embodiment of the present invention.

FIG. 7 is a diagram of stress curve of ball conducting joints of integrated circuit package component of the present invention comparing to conventional arts.

FIG. 8 is a schematic view illustrating an arrangement means of solder joints of the integrated circuit package component of still one another embodiment of the present invention.

### DESCRIPTION OF THE PREFERRED EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

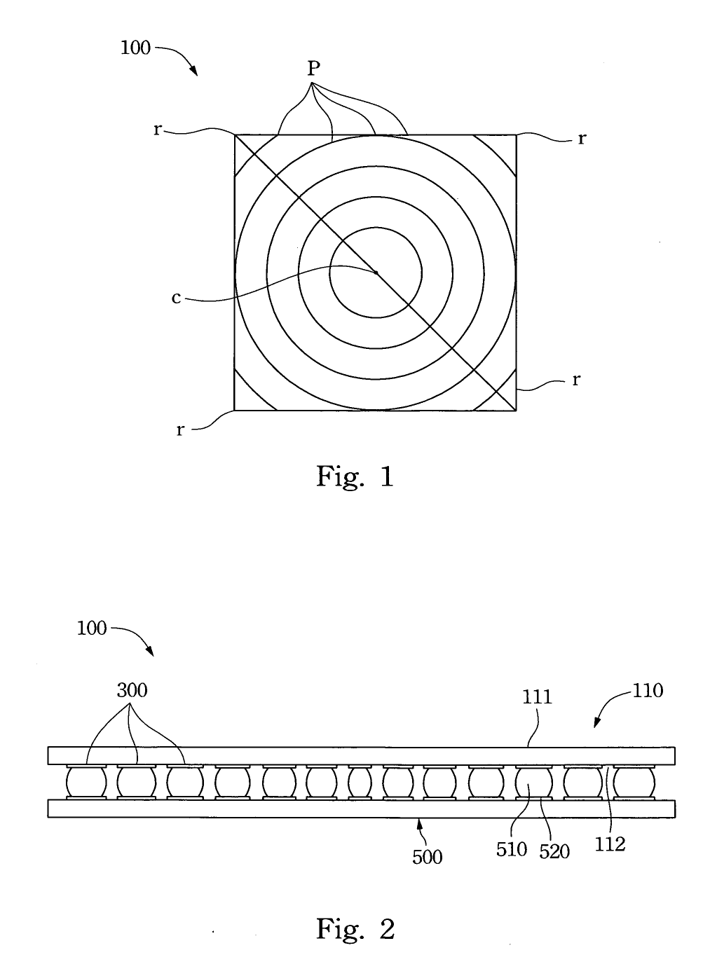

Refer to FIG. 1. FIG. 1 is a distribution diagram of equal stress lines of an integrated circuit package component when being stressed. After an integrated circuit package component 100 is soldered on a circuit board, the equal stress lines P are concentrically distributed from a geometric center c, serving as a circle center, towards the edge of the integrated circuit package component 100 when subject to a mechanical stress or thermal stress, i.e. the further away from the geometric center (c), the stronger the stress is applied. In other words, if the integrated circuit package component 100 is a rectangular shape, the corners (r) thereof are subject to the greatest stress.

The present invention is aimed at altering the arrangement means of solder points soldered on the integrated circuit package component 100, including (1) enlarging the soldering areas of solder joints located close to the edge of the integrated circuit package component 100 and (2) increasing the amount of solder joints distributed on the same equal stress line of integrated circuit package component 100, for enhancing the strength of the integrated circuit package component 100.

Refer to FIG. 2. FIG. 2 is a cross sectional view of the integrated circuit package component of one embodiment of the present invention being soldered on a circuit board. The present invention provides an integrated circuit package component 100 with ball conducting joints, comprises a substrate 110 and a plurality of solder joints 300. The substrate 110 is formed with a first surface 111 and a second surface 112 opposite to the first surface 111. The solder joints 300 are provided on the second surface 112 and arranged to form a pattern of a concentric array and expanded towards the edge of the second surface 112. The integrated circuit package component is able to be soldered on solder pads 520 of a circuit board 500 through soldering the solder joints 300 with solder balls 510. What shall be illustrated is that, in this embodiment, the solder pads 520 are matched and correspond to the solder joints 300. For example, if the soldering area of a certain solder joint 300 is relatively larger, the corresponding solder pad 520 is enlarged, and the solder ball 510 installed between the solder joint 300 and the solder pad 520 is also correspondingly enlarged, as shown in FIG. 2.

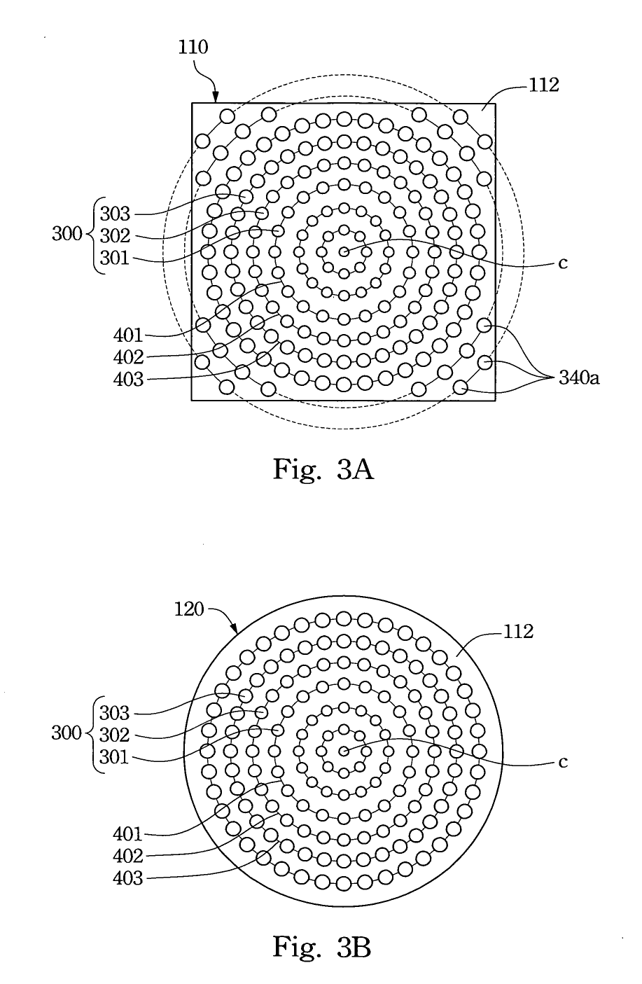

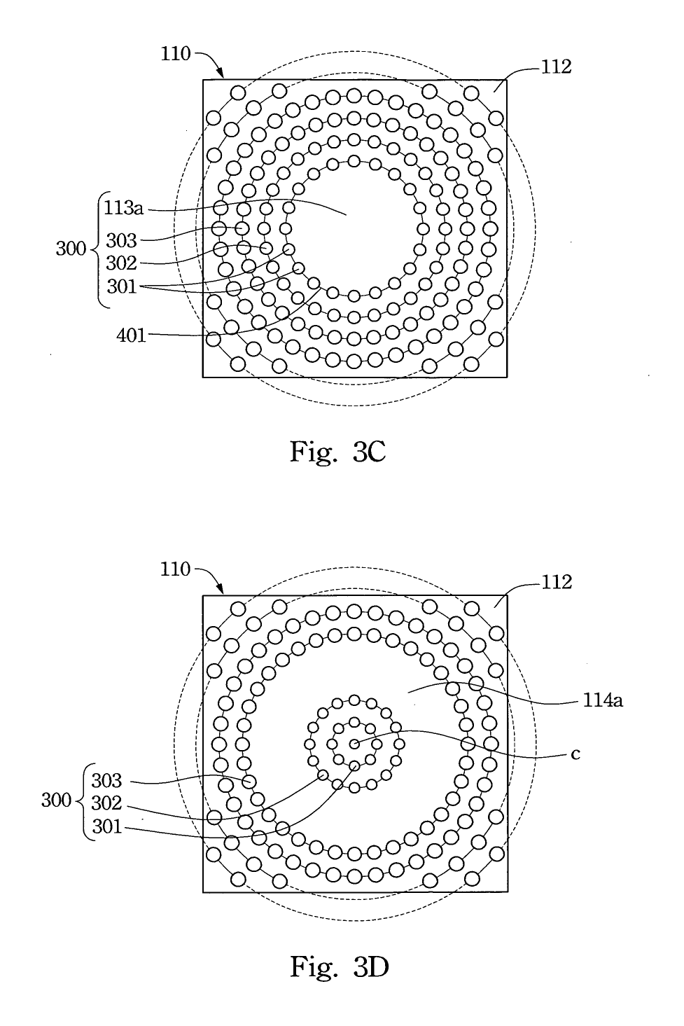

Refer to FIG. 3A. FIG. 3A is a schematic view illustrating an arrangement means of solder joints of the integrated circuit package component of one embodiment of the present invention. The solder joints 300 are arranged to form a concentric circle array. The concentric circle array can be defined as a plurality of gradually-enlarged circles encircling with each other. The soldering areas of the solder joints 300 on the same circle of the concentric circle array are the same. And the solder joints 300 disposed at the outer circle of the concentric circle array have larger soldering areas. In other words, the soldering areas of the solder joints 300 on each circle are in sequence enlarged from the geometric center (c) of the second surface 112 towards the edge of the second surface 112.

For instance, the solder joints 300 includes plural first solder joints 301, plural second solder joints 302 and plural third solder joints 303. The first solder joints 301 are arranged to form a first circle 401 (first zone), and the first circle 401 encircles the geometric center (c). The second solder joints 302 are arranged to form a second circle 402 (second zone), and the second circle 402 encircles the whole first circle 401 (the second zone encircles the first zone), wherein the soldering areas of the first solder joints 301 are smaller than that of the second solder joints 302. The third solder joints 303 are arranged to form a third circle 403 (third zone), and the third circle 403 encircles the whole second circle 402 (the third zone encircles the second zone and the first zone), wherein the soldering areas of the second solder joints 302 are smaller than that of the third solder joints 303.

Accordingly, soldering areas of the solder joints 300 encircled inside the first circle 401 is smaller than the soldering area of any first solder joints 301, and soldering areas of the solder joints 300 arranged outside the third circle 403 is larger than the soldering area of any third solder joints 303.

Refer to FIG. 3B, which is a schematic view illustrating another arrangement means of solder joints of one embodiment of the present invention. In this embodiment, the substrate can be a rectangular substrate 110 (as shown in FIG. 3A) or a round substrate 120 (as shown in FIG. 3B), wherein the arrangement means of the round substrate 120 is the same as the rectangular substrate 110.

Moreover, on the rectangular substrate 110, beside the solder joints 300 that can be arranged to form complete round patterns, four corners of the rectangular substrate 110 can also be respectively provided with edge solder joints 340a (as shown in FIG. 3A). The edge solder joints 304a are not able to be arranged as a compete round pattern, and the soldering areas of the edge solder joints 304a are larger than that of the solder joints 300 capable of being arranged as a complete round pattern.

Refer to FIG. 3C. FIG. 3C is a schematic view illustrating another method of arranging solder joints of one embodiment of the present invention. With considerations of heat dissipation and electricity, the second surface 112 is further provided with a first non-solder zone 113a. The first non-solder zone 113a is at the location of the geometric center (c), and is encircled by the solder joints 300 arranged on the innermost circle of the concentric circle array.

Refer to FIG. 3D. FIG. 3D is a schematic view illustrating still another method of arranging solder joints of one embodiment of the present invention. The second surface 112 is further provided with a second non-solder zone 114a disposed between the solder joints 300 arranged on the innermost circle and the solder joints 300 arranged on the outermost circle of the concentric circle array.

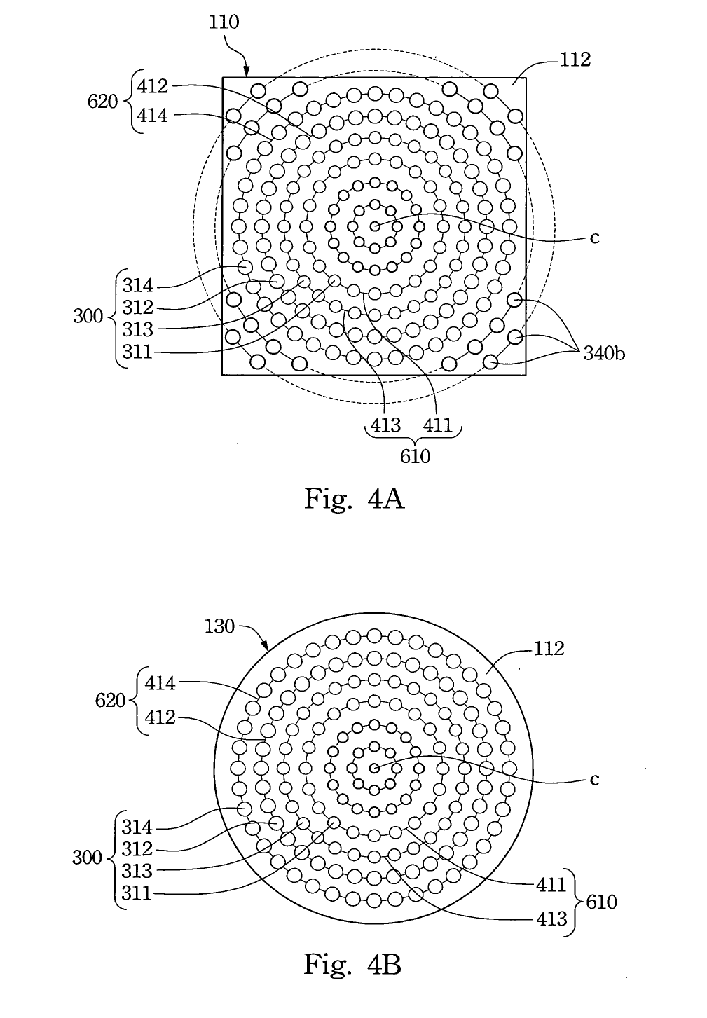

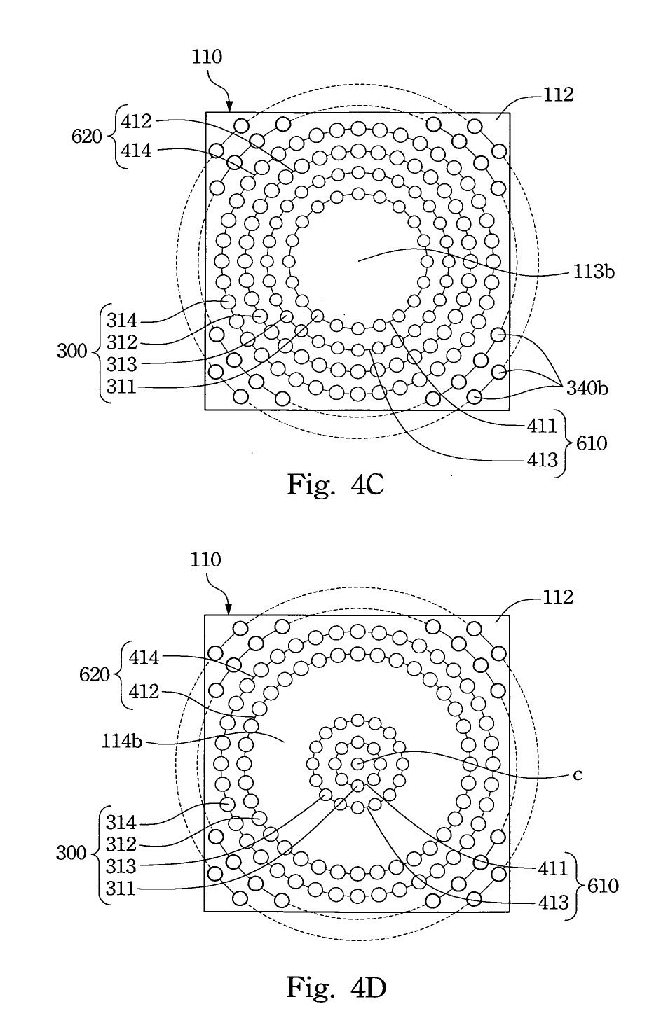

Refer to FIG. 4A. FIG. 4A is a schematic view illustrating an arrangement means of solder joints of the integrated circuit package component of another embodiment of the present invention. The solder joints 300 are arranged to form a concentric circle array. The concentric circle array can be defined as a plurality of round groups encircled in sequence. Each round group can be defined as a plurality of patterns gradually-expanded and encircled in sequence. Any two solder joints 300 in the same round group have the same soldering areas. The soldering area of any solder joint 300 installed in the inner circle of the round group is smaller than that of any solder joint 300 installed at the outer circle of the round group.

For example, the solder joints 300 includes plural first solder joints 311, plural second solder joints 312, plural third solder joints 313 and plural fourth solder joints 314. The first solder joints 311 are arranged to form a first circle 411, and the first circle 411 encircles the geometric center (c). The third solder joints 313 are arranged to form a third circle 413, and the third circle 413 encircles the whole first circle 411. The second solder joints 312 are arranged to form a second circle 412. The second circle 412 encircles the third circle 413, the first circle 411 and the geometric center (c). The fourth solder joints 314 are arranged to form a fourth circle 414 (fourth zone). The fourth circle 414 encircles the second circle 412, the third circle 413, the first circle 411 and the geometric center (c). The first solder joints 311 and the third solder joints 313 have the same soldering areas due to the first circle 411 and the third circle 413 are both belonged to a first round group 610 (first zone). The second solder joints 312 and the fourth solder joints 314 have the same soldering areas due to the second circle 412 and the fourth circle 414 are both belonged to a second round group 620 (second zone).

Moreover, the soldering areas of the second solder joints 312 (or the fourth solder joints 314) are larger than that of the first solder joints 311 (or the third solder joints 313). Accordingly, the solder joints 300 of the round group closer to the edge of the second surface 112 have larger soldering areas.

The difference between FIG. 4A and FIG. 3A is that, in FIG. 3A, the solder joints 300 located at different circles have different soldering areas, while in FIG. 4A, the solder joints 300 located at different circles but still belonged to the same round group have the same soldering areas.

Refer to FIG. 4B. FIG. 4B is a schematic view illustrating another arrangement means of solder joints of the integrated circuit package component of another embodiment of the present invention. In this embodiment, the substrate can be a rectangular substrate 110 (as shown in FIG. 4A) or a round substrate 130 (as shown in FIG. 4B); wherein the arrangement means of the round substrate 130 is the same as the rectangular substrate 110. Moreover, on the rectangular substrate 110, besides the solder joints 300 that can be arranged as a complete round pattern, four corners of the rectangular substrate 110 can also be respectively provided with an edge solder joint 340b (as shown in FIG. 4A). The edge solder joints 304b are not able to be arranged as a compete round pattern, and the soldering areas of the edge solder joints 304b are larger than that of the solder joints 300 capable of being arranged as a complete round pattern.

Refer to FIG. 4C. FIG. 4C is a schematic view illustrating another method of arranging solder joints of the integrated circuit package component of another embodiment of the present invention. With considerations of heat dissipation and electricity, the second surface 112 is further formed with a first non-solder zone 113b covering the location of the geometric center (c), and is encircled by the solder joints 300 arranged on the innermost circle of the first round group 610 (first zone) of the concentric circle array. Refer to FIG. 4D, which is a schematic view illustrating still another method of arranging solder joints of the integrated circuit package component of another embodiment of the present invention. The second surface 112 is further formed with a second non-solder zone 114b disposed between the solder joints 300 arranged on the innermost circle and the solder joints 300 arranged on the outermost circle of the concentric circle array. The second non-solder zone 114b is defined between the first round group 610 (first zone) and the second round group 620 (second zone).

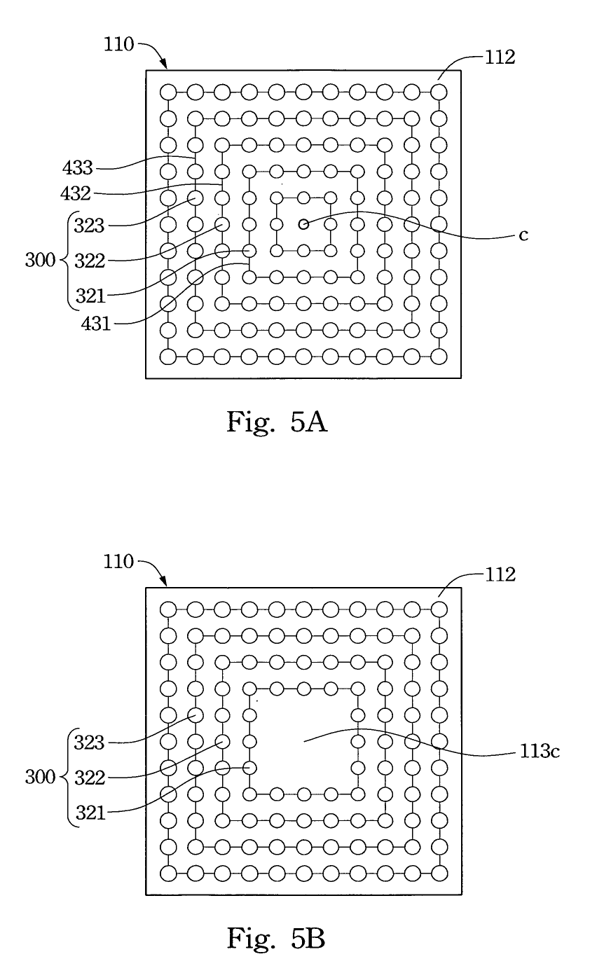

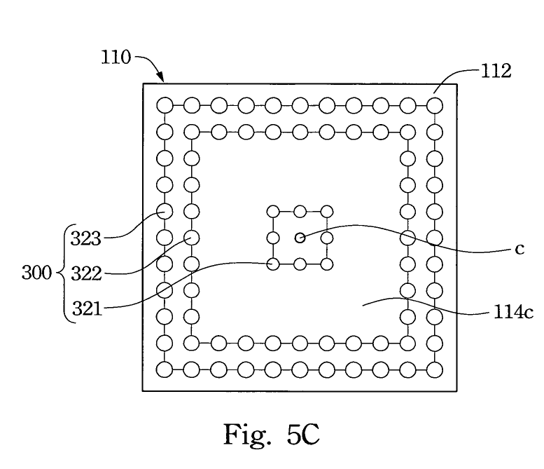

Refer to FIG. 5A. FIG. 5A is a schematic view illustrating an arrangement means of solder joints of the integrated circuit package component of one another embodiment of the present invention. In this embodiment, the concentric array is a concentric rectangular array formed by a plurality of rectangular patterns (preferably square patterns) gradually expanded and in sequence surrounded with each other. The solder joints 300 installed on the same rectangular pattern of the concentric rectangular array have the same soldering areas. The solder joints 300 installed on the outer rectangular pattern of the concentric rectangular array have larger soldering areas. In other words, the soldering areas of the solder joints 300 are in sequence enlarged from the geometric center (c) of the second surface 112 towards the edge of the second surface 112.

For instance, the solder joints 300 includes plural first solder joints 321, plural second solder joints 322 and plural third solder joints 323. The first solder joints 321 are arranged to form a first rectangle 431 (first zone), and the first rectangle 431 encircles the geometric center (c) of the second surface 112. The second solder joints 322 are arranged to form a second rectangle 432 (second zone), and the second rectangle 432 encircles the first rectangle 431 (the second zone encircles the first zone), wherein the soldering areas of the first solder joints 321 are smaller than that of the second solder joints 322. The third solder joints 323 are arranged to formed a third rectangle 433 (third circle), and the third rectangle 433 encircles the second rectangle 432 (the third zone encircles the second are and the first zone), wherein the soldering areas of the second solder joints 322 are smaller than that of the third solder joints 323.

Accordingly, the soldering areas of the solder joints 300 encircled inside the first rectangle 431 are smaller than any soldering area of the first solder joints 321, and the soldering areas of the solder joints 300 arranged outside the third rectangle 433 are larger than the soldering areas of the third solder joints 323.

The substrate, in this embodiment, can be a rectangular substrate 110 (as shown in FIG. 5A) or a round substrate (not shown).

Refer to FIG. 5B. FIG. 5B is a schematic view illustrating another method of arranging solder joints of the integrated circuit package component of one another embodiment of the present invention. With considerations of heat dissipation and electricity, the second surface 112 is further formed with a first non-solder zone 113c at the location of the geometric center (c), and is encircled by the solder joints 300 arranged on the innermost rectangle of the concentric rectangular array. The first non-solder zone 113c is encircled by the solder joints 300 of the first rectangle 431 (first zone). Refer to FIG. 5C, which is a schematic view illustrating another method of arranging solder joints of the integrated circuit package component of one another embodiment of the present invention. The second surface 112 is further formed with a second non-solder zone 114c disposed between the solder joints 300 of the innermost rectangle and the solder joints 300 of the outermost rectangle of the concentric rectangular array. The second non-solder zone 114c is defined between the first rectangle 431 (first zone) and the second rectangle 432 (second zone).

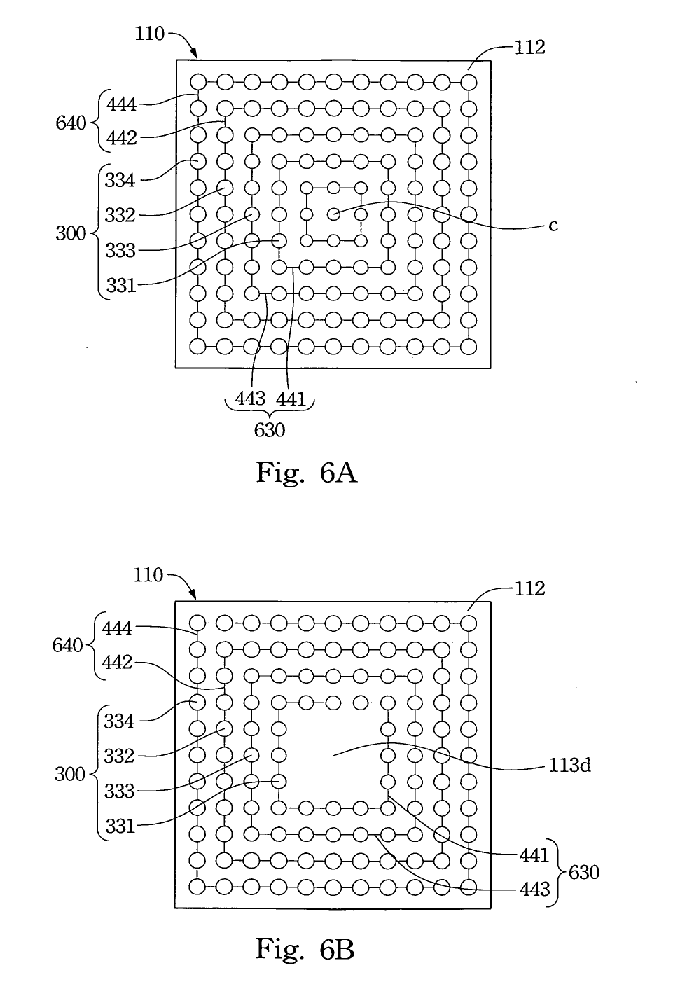

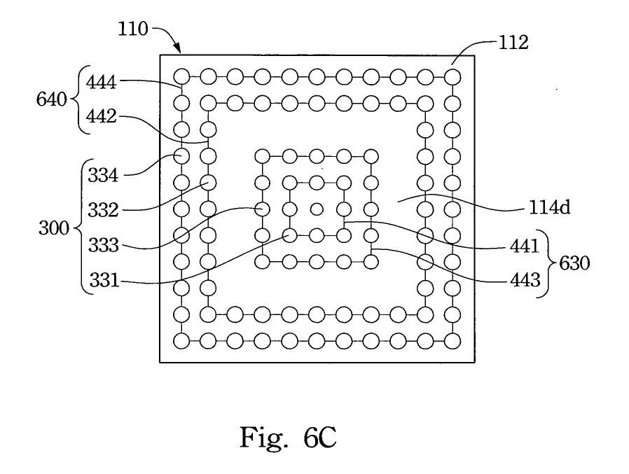

Refer to FIG. 6A, which is a schematic view illustrating an arrangement means of solder joints of the integrated circuit package component of still one another embodiment of the present invention. The solder joints 300, in this embodiment, are arranged to form a concentric rectangular array. The concentric rectangular array can be defined as a plurality of rectangular groups encircled in sequence. Each rectangular group can be defined as a plurality of rectangular patterns gradually-expanded and encircled in sequence. Any two solder joints 300 in the same rectangular group have the same soldering areas. The soldering area of any solder joint 300 installed in the inner rectangle of the rectangular group is smaller than that of any solder joint 300 installed at the outer rectangle of the rectangular group.

For instance, the solder joints 300 includes plural first solder joints 331, plural second solder joints 332, plural third solder joints 333 and plural fourth solder joints 334. The first solder joints 331 are arranged to form a first rectangle 441 (first zone), and the first rectangle 441 encircles the geometric center (c). The third solder joints 333 are arranged to form a third rectangle 443, and the third rectangle 443 encircles the whole first rectangle 441. The second solder joints 332 are arranged to form a second rectangle 442. The second rectangle 442 encircles the third rectangle 443, the first rectangle 441 and the geometric center (c). The fourth solder joints 334 are arranged to form a fourth rectangle 444. The fourth rectangle 444 encircles the second rectangle 442, the third rectangle 443, the first rectangle 441 and the geometric center (c). The first solder joints 331 and the third solder joints 333 have the same soldering areas, due to the first rectangle 441 and the third rectangle 443 are both belonged to a first rectangular group 630 (first zone). The second solder joints 332 and the fourth solder joints 334 have the same soldering areas due to the second rectangle 442 and the fourth rectangle 444 are both belonged to a second rectangular group 640 (second zone). Moreover, the soldering areas of the second solder joints 332 (or the fourth solder joints 334) are larger than that of the first solder joints 331 (or the third solder joints 333).

Accordingly, closer to the edge of the second surface 112, the soldering areas of the solder joints 300 of the rectangular group are larger.

In this embodiment, the substrate can be a rectangular substrate 110 (as shown in FIG. 6A) or a round substrate (not shown).

Refer to FIG. 6B, which is a schematic view illustrating another method of arranging solder joints of the integrated circuit package component of still one another embodiment of the present invention. With considerations of heat dissipation and electricity, the second surface 112 is further formed with a first non-solder zone 113d covering the location of the geometric center (c), and is encircled by the solder joints 300 arranged on the innermost rectangle of the first rectangular group 630 (first zone) of the concentric rectangular array.

Refer to FIG. 6C, which is a schematic view illustrating another method of arranging solder joints of the integrated circuit package component of still one another embodiment of the present invention. The second surface 112 is further formed with a second non-solder zone 114d disposed between the solder joints 300 of the innermost rectangle and the solder joints 300 of the outermost rectangle of the concentric rectangular array. The second non-solder zone 114d is defined between the first rectangular group 630 (first zone) and the second rectangular group 640 (second zone).

Based on the mentioned embodiments, the solder joints 300 further define a central solder joint c. The central solder joint c is located at the geometric center (c) of the second surface 112, so the soldering area of the central solder joint c is smaller than that of all the solder joints 300 encircling the geometric center (c).

Based on the mentioned embodiments, the diameter of the largest soldering area of the solder joints 300 is 0.39±0.05 mm; the diameter of the smallest soldering area of the solder joints 300 is 0.32±0.05 mm.

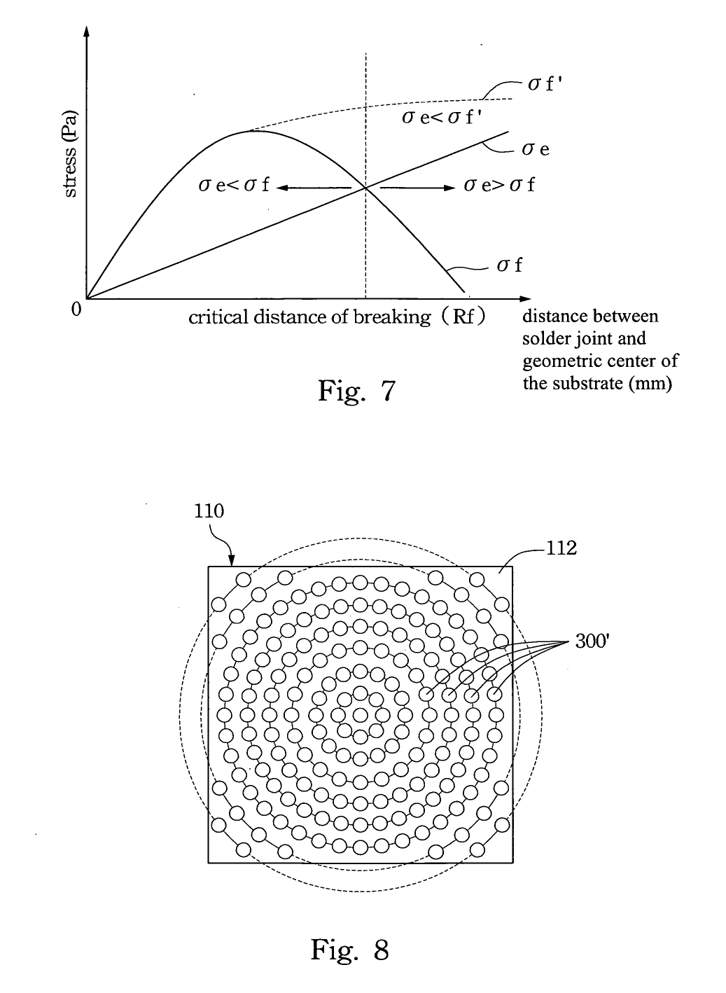

With respect to the above disclosures, and Refer to FIG. 3A and FIG. 7, wherein FIG. 7 is a diagram of a stress curve of ball conducting joints of integrated circuit package component of the present invention comparing to conventional arts.

In FIG. 7, σe is the stress applied to the solder joint, σf is the strength (critical stress) of solder joint breaking of conventional unit. When the distance between the solder joint of conventional integrated circuit package component and the chip center is greater than the critical distance (Rf) of solder joint breaking , the stress σe applied to the solder joint is larger the critical stress σf of solder joint breaking, so the solder joint located at the critical distance (Rf) of solder joint breaking is more likely to be broken.

According to the present invention, the soldering area of solder joint on the substrate 110 is gradually enlarged towards the edge of the substrate, and the amount of solder joints on a same equal stress line is increased (as shown in FIG. 8) so as to enhance the strength. When the integrated circuit package component 100 of the present invention is applied with an external stress (σe) with respect to a critical distance (Rf) of the substrate 110, because the strength (critical stress) σf′ is greater than the external stress (σe), the solder joint 300 of the present invention located at the critical distance (Rf) is less likely to be broken.

Refer to FIG. 8. FIG. 8 is a schematic view illustrating an arrangement means of solder joints of the integrated circuit package component of still one another embodiment of the present invention. The solder joints 300′ are arranged to form a concentric circle array. The concentric circle array can be defined as a plurality of gradually-expanded round patterns encircled in sequence. All of the solder joints 300′ in the concentric circle array have the same soldering areas (if any different soldering area exists then it shall be categorized to FIG. 3A).

In this embodiment, the soldering areas of the solder joints 300′ relatively closer to the edge of the second surface 112 are not larger than that of other solder joints 300′ farer away from the edge of the second surface 112, the amount of solder joints 300′ on an equal stress line of the substrate 110 is greater than the amount of solder joints arranged with a conventional square rectangular array means, thus, the greater strength is also provided.

The first non-solder zone 113a as shown in FIG. 3C or the second non-solder zone 114a as shown in FIG. 3D can be adopted in this embodiment.

Accordingly, with the feature of concentric distribution of stress for integrated circuit package component, the present invention has provided the mentioned means for reinforcing the strength of solder joints. Thus the structural strength of integrated circuit package component installed on a printed circuit board is enhanced, so as to increase the anti-fatigue capability and reliability of the integrated circuit package component, and the size of integrated circuit package component is also reduced.

The reader's attention is directed to all papers and documents which are filed concurrently with his specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. An integrated circuit package component with ball conducting joints, comprising:
a substrate having a first surface and a second surface opposite to the first surface; and
a plurality of solder joints arranged on the second surface to form a concentric array for being soldered on a circuit board, the concentric array comprising a first zone and a second zone encircling the first zone,
wherein a soldering area of each solder joint in the first zone is smaller than a soldering area of each solder joint in the second zone.

2. The integrated circuit package component with ball conducting joints according to claim 1, wherein the concentric array is a concentric circle array, the first zone and the second zone are respectively shaped as a round shape.

3. The integrated circuit package component with ball conducting joints according to claim 1, wherein the first zone is a first round group comprising a plurality of round patterns in sequence encircled, the solder joints of the first round group have the same soldering areas,
the second zone is a second round group comprising a plurality of round patterns in sequence encircled, the solder joints of the second round group have the same soldering areas.

4. The integrated circuit package component with ball conducting joints according to claim 1, wherein the concentric array is a concentric rectangular array, the first zone and the second zone are respectively shaped as a rectangular shape.

5. The integrated circuit package component with ball conducting joints according to claim 1, wherein the first zone is a first rectangular group comprising a plurality of rectangular patterns in sequence encircled, the solder joints of the first rectangular group have the same soldering areas,
the second zone is a second rectangular group comprising a plurality of rectangular patterns in sequence encircled, the solder joints of the second rectangular group have the same soldering areas.

6. The integrated circuit package component with ball conducting joints according to claim 1, wherein the second surface is further formed with a first non-solder zone located at a geometric center of the second surface and encircled by the first zone.

7. The integrated circuit package component with ball conducting joints according to claim 1, wherein the second surface is further formed with a second non-solder zone located between the first zone and the second zone.

8. The integrated circuit package component with ball conducting joints according to claim 1, wherein the substrate further comprises a geometric center encircled by the first zone and the second zone.

9. An integrated circuit package component with ball conducting joints, comprising:
a substrate having a first surface and a second surface opposite to the first surface;
a plurality of first solder joints respectively arranged on the second surface to define a first zone; and
a plurality of second solder joints respectively arranged on the second surface to define a second zone, the second zone encircles the first zone, wherein soldering areas of the first solder joints are smaller than soldering areas of the second solder joints.

10. The integrated circuit package component with ball conducting joints according to claim 9, wherein the first zone and the second zone respectively form as a round pattern or a rectangular pattern.

11. The integrated circuit package component with ball conducting joints according to claim 9, further comprising a central solder joint located at a geometric center of the second surface thereof, wherein a soldering area of the central solder joint is smaller than a soldering area of each first solder joint.

12. An integrated circuit package component with ball conducting joints, comprising:
a substrate having a first surface and a second surface opposite to the second surface; and
a plurality of solder joints respectively arranged on the second surface to form a concentric circle array defined by a plurality of gradually-enlarged circles in sequence encircled, soldering areas of the solder joints on the circles are the same.

13. The integrated circuit package component with ball conducting joints according to claim 12, wherein the second surface further comprises a first non-solder zone located at a geometric center of the second surface thereof, and is encircled by the solder joints of the innermost circle of the plural circles.

14. The integrated circuit package component with ball conducting joints according to claim 12, wherein the second surface further comprises a second non-solder zone disposed between the solder joints of the innermost circle and the solder joints of the outermost circle of the plural circles.
